(19) United States
(12) Patent Application Publication
(10) Pub. No.: US 2012/0026704 A1
(43) Pub. Date: Feb. 2, 2012

(54) SINGLE-BOARD WIRELESS NETWORKING ADAPTOR WITH INTEGRAL HIGH-GAIN DIRECTIONAL ANTENNA

(75) Inventor: Thomas J. DiClemente, Hummelstown, PA (US)

(73) Assignee: hField Technologies, Inc., Bethlehem, PA (US)

(21) Appl. No.: 13/191,781

(22) Filed: Jul. 27, 2011

Related U.S. Application Data
(60) Provisional application No. 61/368,100, filed on Jul. 27, 2010.

(51) Int. Cl. H05K 7/06; H01Q 21/28; H01Q 1/42; H01Q 19/30

(52) U.S. Cl. 361/759; 343/819; 343/727; 343/872

(57) ABSTRACT

A wireless networking adapter integrated in an impedance-controlled manner with at least one directional antenna and, optionally, an omni-directional antenna to achieve maximum signal strength and integrity for a given antenna size for maximum distance performance.

### CROSS REFERENCE TO RELATED APPLICATIONS

This application claims the benefit of U.S. Provisional Application No. 61/368,100, filed Jul. 27, 2010, the entire contents of which are incorporated by reference herein as if fully set forth.

### BACKGROUND OF THE INVENTION

This invention relates to a wireless device for use in a local area network (LAN).

Most current wireless networking adapters use an omni-directional antenna, which has a maximum operating range of 300 feet but in reality far below this distance due to obstructions, elevation differences and interference from other high frequency devices and equipment. In many operating environments, it is desirable to have a greater operating range and the flexibility of connecting in difficult environments containing obstructions, interference and elevation differences.

There have been some attempts to use directional antennas with wireless networking adapters. Some use an auxiliary antenna that is used as an add-on to an existing wireless networking adapter. Such devices are undesirable because they are bulky, difficult to aim, and result in only negligible improvements in operating range unless very large and bulky antennae are used. The connections necessary tend to introduce high losses which negate the gain of the add-on antenna.

There have been some attempts to provide a wireless networking adapter with a directional antenna included therein. Many of these devices use large directional antennas, such as a parabolic antenna, and therefore, are inconvenient to use, especially for laptop users. Those devices that use smaller directional antennas, such as a microstrip patch, provide little improvement in operating range. Larger patch antennae are bulky and do not provide precise directionality.

Current add-on and included directional antennas tend to use simplified designs that are lossy and provide distortion to the signal, thereby partially negating the gain of the antenna

It is desirable to have a wireless networking adapter with a directional antenna located therein that provides for improved operating range over known devices.

### SUMMARY OF THE INVENTION

In one aspect, the invention comprises a wireless networking adapter including an integrated on-board directional antenna that is adapted to send and receive wireless signals of a first protocol (in one aspect, 2.4 Ghz Wi-Fi). The directional antenna preferably includes at least one driven element positioned between a reflector element and at least two director elements. The adapter also includes a decoder circuit that translates wireless signals received through the directional antenna from the first protocol to a second protocol and transmits signals in accordance with the second protocol via a first connector and receives wireless signals through the first connector from the second protocol to the first protocol and transmits signals in accordance with the first protocol via the directional antenna. The first connector is electrically or wirelessly connected to a computer, or other device containing a microprocessor such as a PDA, smart phone or tablet computer, transmits signals to the computer or other device, and receives signals from the computer, or other device electrically or wirelessly, the signals being in accordance with the second protocol.

In a second aspect, the invention comprises a wireless networking adapter including an integrated on-board directional antenna that is adapted to send and receive wireless signals of multiple protocols (as an example, in the second aspect, both 2.4 Ghz and 5 GHz Wi-Fi simultaneously). In this second aspect, the invention may contain one directional antenna integrated with the electronics or a plurality of directional antennae on the same printed circuit board and integrated with the electronics.

In a third aspect, the invention comprises a wireless networking adapter including an integrated on-board directional antenna that is adapted to send and receive wireless signals of multiple protocols (as an example, in the third aspect, both 2.4 Ghz and 5 GHz Wi-Fi simultaneously) as well as employ 802.11n protocols including MIMO or multiple in-multiple out techniques which may employ multiple radios. In this third aspect, the invention may contain one directional antenna integrated with the electronics or a plurality of directional and omni-directional antennae on the same printed circuit board and integrated with the electronics.

In a fourth aspect, the invention comprises a wireless networking adapter including an integrated on-board directional antenna that is adapted to send and receive wireless signals of multiple non-Wi-Fi protocols (as an example, in the fourth aspect, over frequency bands different than and possibly wider than Wi-Fi frequency bands for example for Wi-Max, LTE or private, licensed communications bands, for example, in the range of 2 GHz to 12 GHz), which may also employ multiple radios. In this fourth aspect, the invention may contain one directional antenna integrated with the electronics or a plurality of directional and omni-directional antennae on the same printed circuit board and integrated with the electronics.

In a fifth aspect, the invention may be realized in any of the first four aspects but as a second protocol, for communications with the computer or other microprocessor-containing device, utilize a wireless protocol, which may be Wi-Fi, Bluetooth, or a proprietary protocol, for communications with the microprocessor-containing device.

### BRIEF DESCRIPTION OF THE DRAWINGS

FIG. 1 is a block diagram showing one embodiment of a wireless networking adapter of the present invention;

FIG. 2 is a block diagram showing an alternative embodiment of a wireless networking adapter of the present invention;

FIG. 3 is a perspective view of one embodiment of a wireless networking adapter according to the present invention, also showing a USB cable and a mount interface attached to the wireless networking adapter;

FIG. 4 is a “top” view of a printed circuit board assembly which is housed within the wireless networking adapter of FIG. 3, showing the first aspect of the invention with the signal path of a printed Yagi antenna facing up from the plane of the paper;

FIG. 5 is a “bottom” view of the printed circuit board assembly of FIG. 4, showing the first aspect of the invention with the return path of a printed Yagi antenna facing up from the plane of the paper and connected to ground;

FIG. 6 is a schematic diagram of the printed circuit board assembly of FIG. 4, showing some of the interior dimensions of the board;

FIG. 7A is an assembly drawing of the wireless networking adapter also displaying various features for maintaining impedance control over the length of the Yagi or other directional antenna;

FIG. 7B is a schematic diagram of the case assembly of the wireless networking adapter;

FIG. 8A is a perspective drawing of the wireless networking adapter, with one half of the case transparent, also displaying specially designed latches which aid in impedance control;

FIG. 8B is a line drawing of both halves of the case, showing the latches and including some dimensions of the case design;

FIG. 8C is a schematic view of the placement of the parallel antenna elements on the printed circuit board relative to the edges of the board;

FIG. 9 is a cross-section taken through line 9-9 of FIG. 8A, with the board replaced, depicting one of the specially designed latches which aid in impedance control;

FIG. 10 is a schematic view of the top (first) layer of a second embodiment of a printed circuit board assembly in accordance with the present invention;

FIG. 11 is a schematic view of the second layer of the printed circuit board assembly of FIG. 10;

FIG. 12 is a schematic view of the third layer of the printed circuit board assembly of FIG. 10; and

FIG. 13 is a schematic view of the bottom (fourth) layer of the printed circuit board assembly of FIG. 10.

### DETAILED DESCRIPTION OF THE PREFERRED EMBODIMENT(S)

The following detailed description of the preferred embodiments of the invention will be better understood when read in conjunction with the appended drawings. For the purposes of illustrating the invention, there is shown in the drawings embodiments which are presently preferred. It is understood, however, that the invention is not limited to the precise arrangements and instrumentalities shown in the drawings.

To aid in describing the invention, directional terms may be used in the specification and claims to describe portions of the present invention (e.g., front, rear, left, right, top, bottom, etc.). These directional definitions are intended to merely assist in describing and claiming the invention and are not intended to limit the invention in any way. In addition, reference numerals that are introduced in the specification in association with a drawing figure may be repeated in one or more subsequent figures without additional description in the specification in order to provide context for other features.

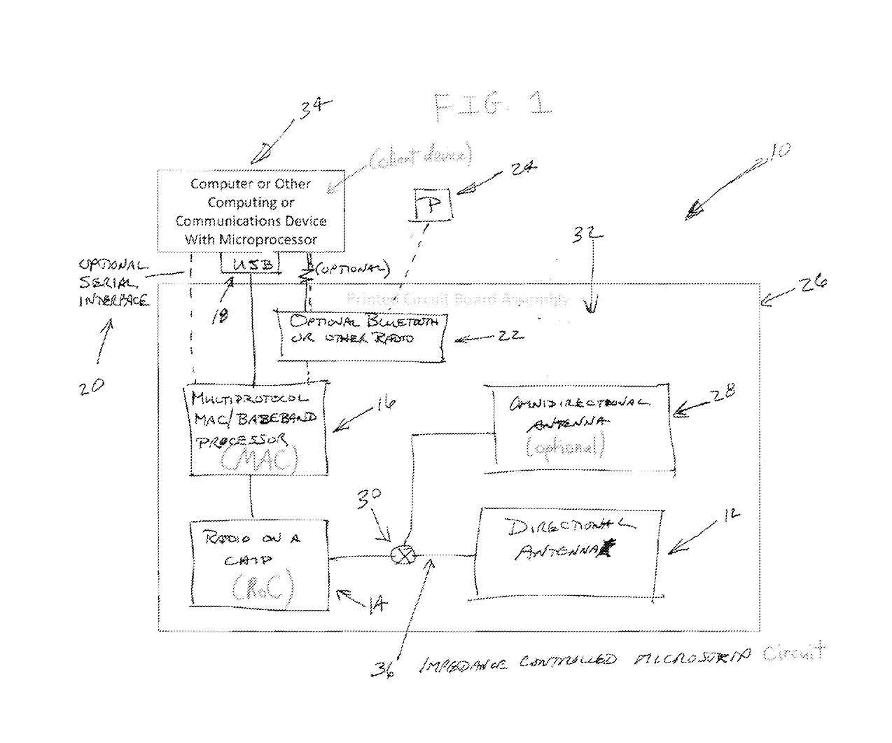

Referring now to FIG. 1, reference numeral 10 generally refers to a wireless networking adapter in accordance with the present invention. This embodiment of the wireless networking adapter 10 includes a directional antenna 12, a Radio on a Chip (RoC) radio transmitter 14, a media access controller/baseband microprocessor (MAC) 16, a USB connector 18, or optionally a connector and alternative serial interface 20, or optionally a Bluetooth or other short range radio 22 with optional battery pack or power cube 24 and a protective case 26. The RoC radio transmitter 14 may employ, for example, Direct Sequence Spread Spectrum (DSSS) or Orthogonal Frequency Division Modulation (OFDM) technologies to effect modulation of the amplitude of the signal. The wireless networking adapter 10 may optionally also include an omni-directional antenna 28 in which case it would also include a high frequency splitter/combiner/switch 30. All elements are preferably mounted to a printed circuit board (PCB) 32.

The directional antenna 12 in the first embodiment is preferably a Yagi antenna which will be described in greater detail herein. In this embodiment, the directional antenna 12 is intended to send and receive Wi-Fi wireless signals, which are wireless signals configured in accordance with one or more of the IEEE 802.11b, 802.11g, or 802.11n standards. The wireless networking adapter 10 communicates with the personal computer, PDA, smart phone or other microprocessor based computing or communications (a.k.a. “client”) device 34, preferably using a universal serial bus (USB) standard but optionally using an other short range radio 22, for example Bluetooth, or an alternative serial interface 20. The Multiprotocol MAC processor 16 converts Wi-Fi signals received from the directional antenna 12 through an impedance-controlled microstrip circuit 36 to a USB or other optional format, and vice-versa, for signals received from the client device 34 through the USB connector 18, alternative serial interface 20, or other short range radio 22 options. Any suitable Multiprotocol MAC Processor 16 can be used, such as a ZyDAS model ZD 1211 b MAC/Baseband signal conversion chip or the Realtek RTL8188CUS single-chip IEEE 208.11b/g/n 1T1R WLAN controller. The microstrip circuit 36 connecting the directional antenna 12 to the Multiprotocol MAC processor 16 is preferably an impedance-controlled electronic microstrip circuit designed to minimize power and signal quality losses. The USB connector 18 is preferably a USB connector which could be inserted directly into a USB port of the client device 34 or connected using a USB cable (not shown) or, optionally, connected wirelessly via a Bluetooth or other short range radio 22 or by an alternative serial interface 20.

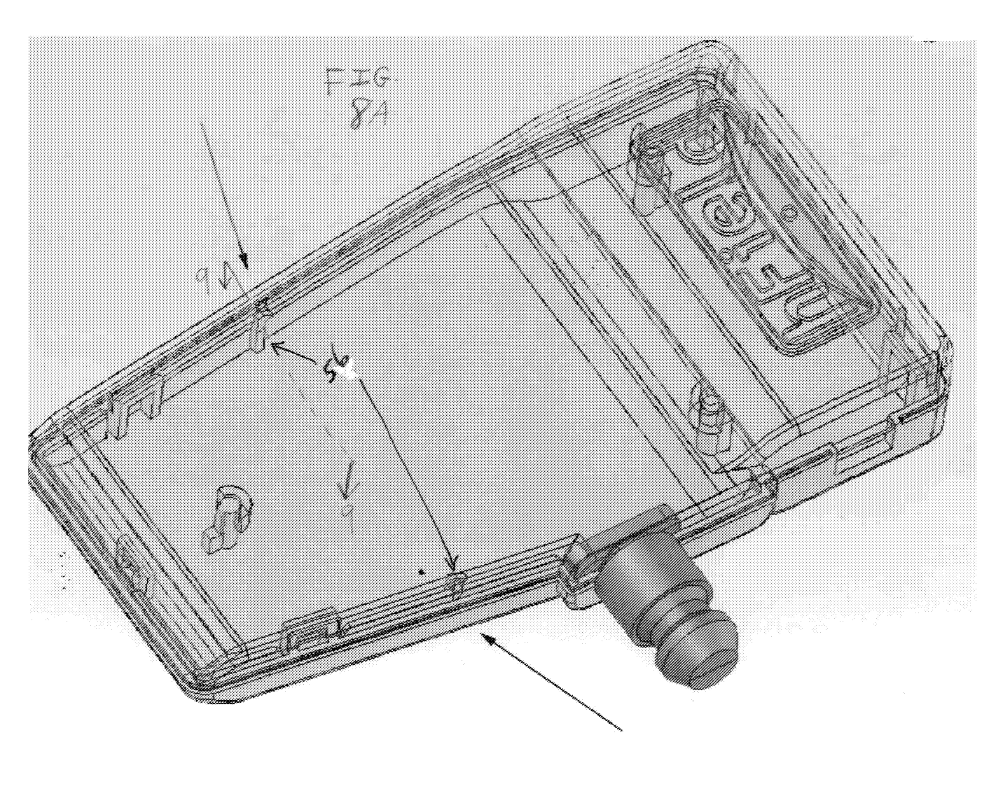

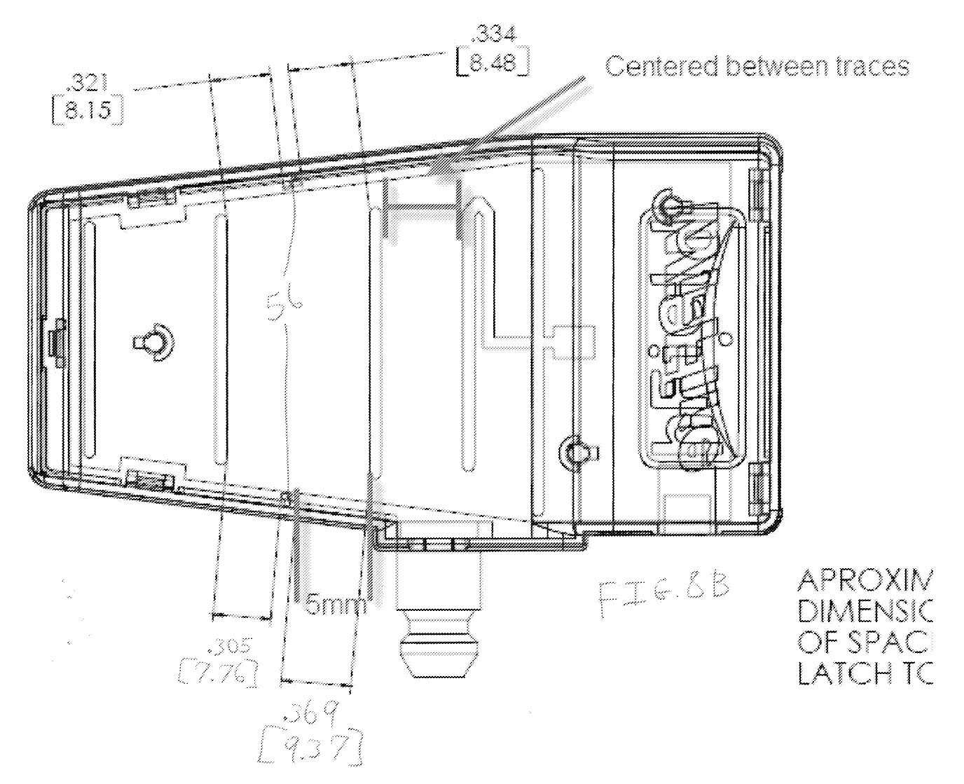

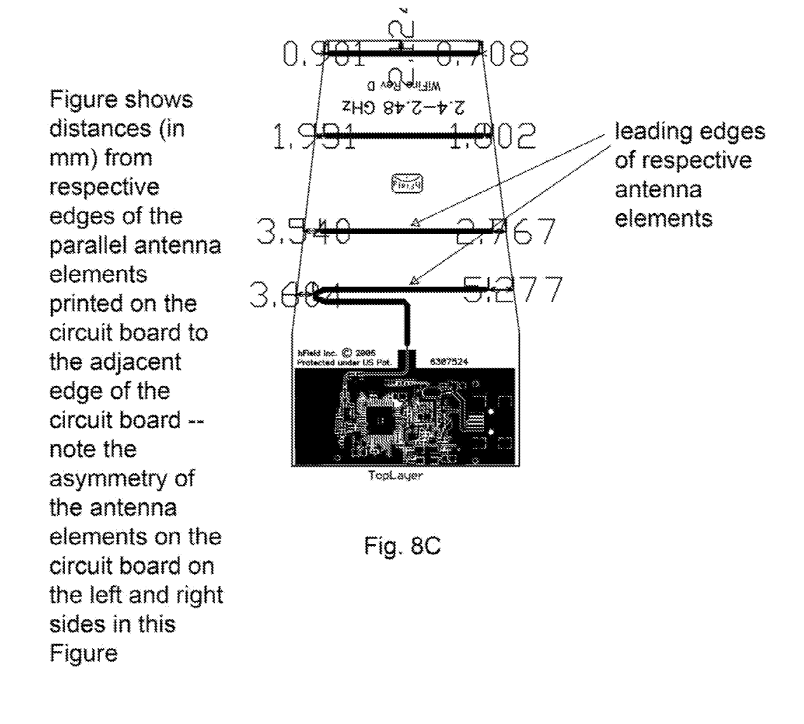

The case 26 is designed to retain and protect the components of the wireless networking adapter 10, but is also designed specifically using impedance control techniques to enhance the performance of the directional antenna 12. The design of the case 26 is such that the gain of the directional antenna 12 without (i.e., when not housed in) the case is significantly less than the gain of the directional antenna 12 with (i.e., when housed in) the case 26. The external design of the case is predetermined for aesthetics and ease of use. The antenna(e) and interface between the antenna(e) and circuitry is then designed to maximize performance within the pre-determined case design. This is achieved by modification of both the internal features of the case and the antenna(e) and antenna(e)/circuitry interface such that the average dielectric constant of the printed circuit board (PCB) 32 plus any air gaps between the end points and leading edges of each antenna element (see FIG. 8C) result in controlled impedance when all three dimensional planes are considered. The “leading edge” of each respective antenna element is the horizontal edge of each element located towards the top of the page in FIG. 8C. PCB modifications include the size and positioning of latches and appurtenances such as the mounting stem. PCB modifications include providing cutouts sized for the desired air gaps and precise control of the distance of the end of each element of the antenna(e) to the edge of the PCB (see FIG. 8C). Contrary to designs resulting from current universally-employed antenna design techniques, the current invention does not necessarily result in symmetry of the antenna(e) elements on the PCB (see FIG. 8C). In the present invention, the dielectric constant of the ABS plastic material of the case 26 is taken into consideration when performing impedance matching. The process of impedance matching is further detailed below.

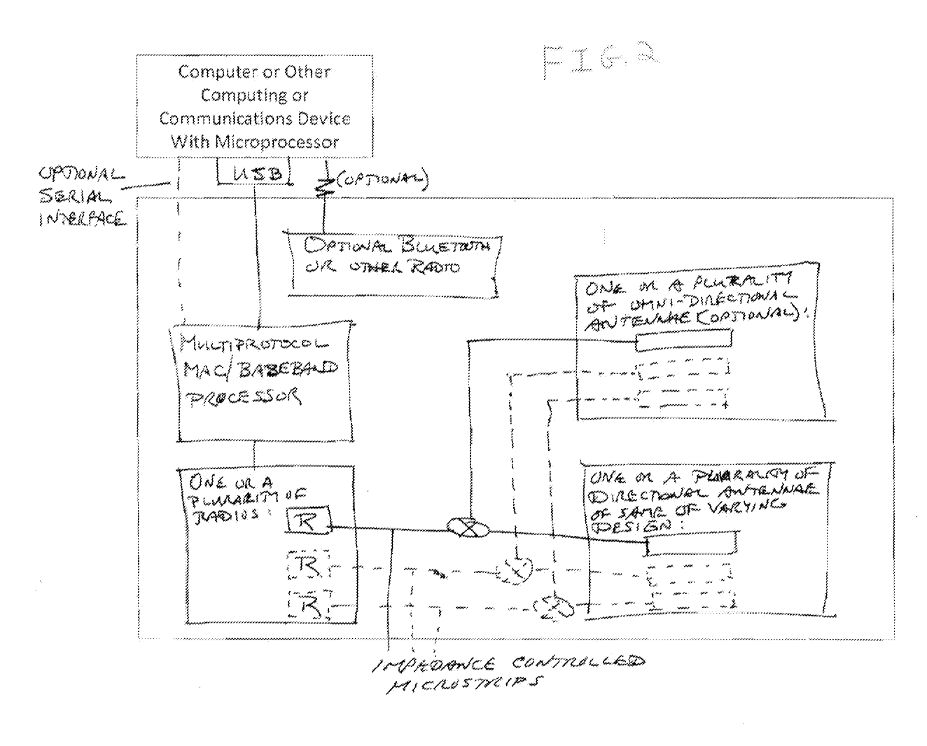

Referring now to FIG. 2, additional embodiments of the first aspect displayed in FIG. 1 are depicted. In particular is the capability to utilize multiple frequency bands, multiple radios and multiple antennae including antennae of varied types in the same assembly. Inherent to all embodiments of the invention is the ability to provide consistent Wi-Fi connectivity at distances of at least three times the distance provided by the Wi-Fi specifications, while still maintaining compliance with Wi-Fi and IEEE 802.11 standards. This is a departure from other “long distance” devices which do not meet all Wi-Fi and 802.11 standards, especially those standards regarding maximum bit error rates. Recently, the 802.11n standard was introduced Inherent to this standard is a further restriction on distance and a steep drop-off in data throughput as distance increases, and hence signal strength, decreases. An advantage of the 802.11n protocol is its improved speed at short range when it is combined with multiple in-multiple out (MIMO) techniques. In this case, at very short ranges and with the use of multiple radios, higher data throughput can be achieved. If multiple radios are used, any suitable MAC processor 16 may be used, for example the Realtek RTL8192CU single-chip IEEE 802.1b/g/n 2T2R WLAN controller. In the embodiments of the invention depicted in FIG. 2, the invention can achieve identical data throughputs as 802.11n with MIMO at short ranges and in addition achieve much higher data throughputs in weak signal, obstructive, interferive and long distance applications than 802.11n with MIMO, achieving the equivalent of 3 to 5 times the distance of other wireless adapters using 802.11n with MIMO as designed to standards preceding the current invention.

In a first set of embodiments of the invention, Yagi antenna(e) are used as the directional antennae for 2.4 GHz protocols. In a second set of embodiments, Yagi and Log Periodic antenna(e) are used on the same substrate to include both 2.4 GHz and 5 GHz protocols. In a third set of embodiments, Log Periodic antenna(e) of special design are used to accommodate multiple frequency bands simultaneously. In some embodiments according to this third set of embodiments, the Log Periodic antenna(e) may be attached to the Multiprotocol MAC processor 16 via coaxial cable(s). In further embodiments, the feed points of the Log Periodic antenna(e) may be connected to the Multiprotocol MAC processor 16 through the same substrate.

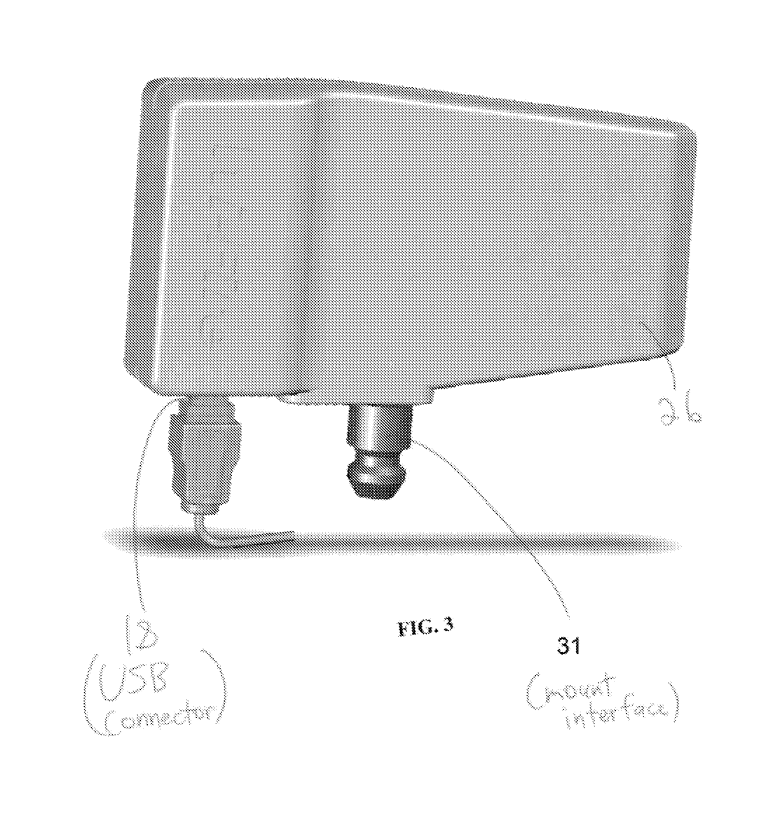

Referring now to FIG. 3, the general shape and configuration of the case 26 is shown. It should be noted that many other possible shapes and configurations for the case 26 could be provided. In this embodiment, the case 26 includes a mount interface 31, which when attached to a base or retaining clip (not shown), enables the case 26 to be positioned in a manner that maximizes signal strength. The case 26 is preferably formed of a polymeric material, such as ABS plastic, for reasons of economy of manufacture, low impedance of microwave signals through thin sections of this material, and durability. As is visible in FIG. 3, in this embodiment the USB connector 18 protrudes through an opening located on the bottom rear side of the case 26.

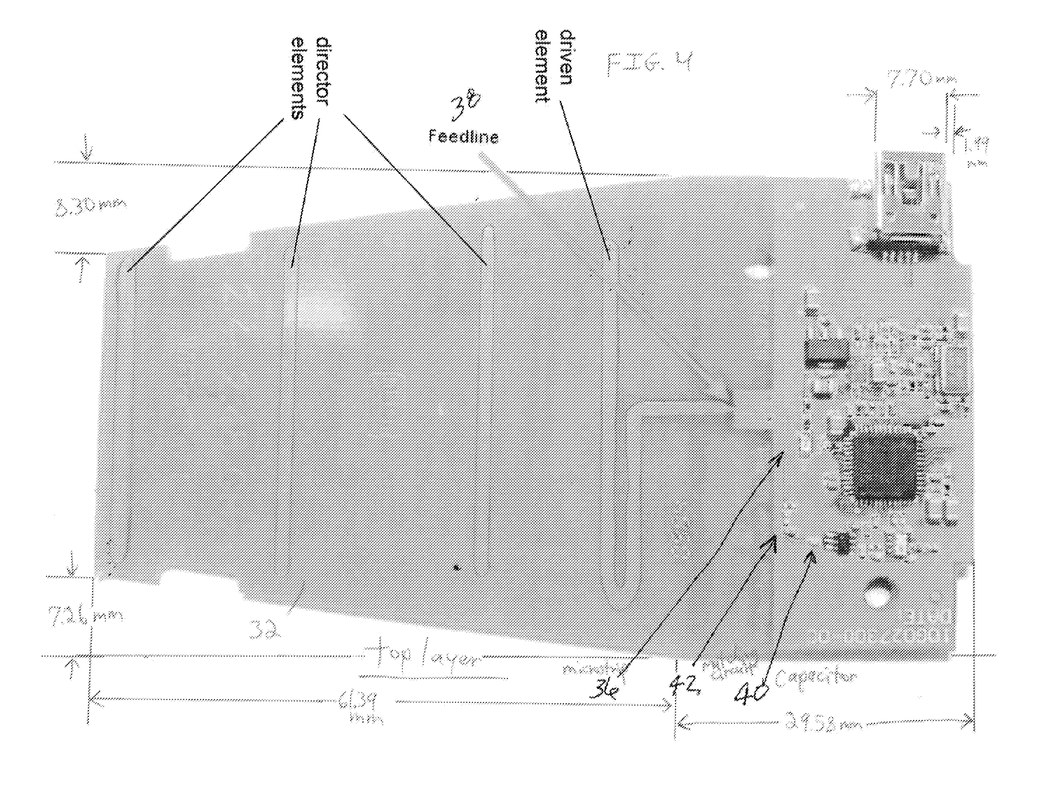

Referring now to FIG. 4, a typical embodiment of the invention is shown. In this embodiment, a directional antenna, in this case a Yagi antenna is integrated onto the same multilayer printed circuit board (“PCB”) 32, together with the Multiprotocol MAC Processor 16 and the RoC radio transmitter 14, without the use of coaxial cables or connectors for impedance control. This embodiment of the invention achieves maximum performance and signal integrity without the use of discrete components for matching impedance. Impedance is controlled through design, careful location, and manufacturing control of the microstrip circuit 36, the feedline 38, with only the use of small capacitance 40 purely for attenuating low frequency noise from the radio in transmit mode. The normal site for the matching circuit 42, as known in the prior art, is identified and pads exist in the circuitry but only for design verification and are not populated in production. This typical embodiment with an integrated directional antenna reduces losses and the resulting degradation in the circuit due to connections, improves signal quality, and provides the opportunity to control impedance over the entire high-frequency signal path. In order to maximize operating range, the directional antenna must be properly tuned and impedance must be controlled and balanced. Proper tuning is particularly difficult when working with high-frequency signal transmission, such as those in the 2.4 Ghz frequency range of Wi-Fi signals. This embodiment of the present invention provides every opportunity to maximize operating range. This embodiment also provides excellent signal strength performance in a very thin and compact manner and results in high power density.

Under field conditions, with clear line of sight, this embodiment of the directional antenna 12 provides an operating range of at least 1000 feet (304.8 meters) and has achieved multiple megabit per second data throughput at an operating range of 1.5 kilometers. Therefore, the present invention provides an improved operating range and usability in a very small form factor, especially in comparison to the operating range of the typical adapter of 300 feet (91.44 meters).

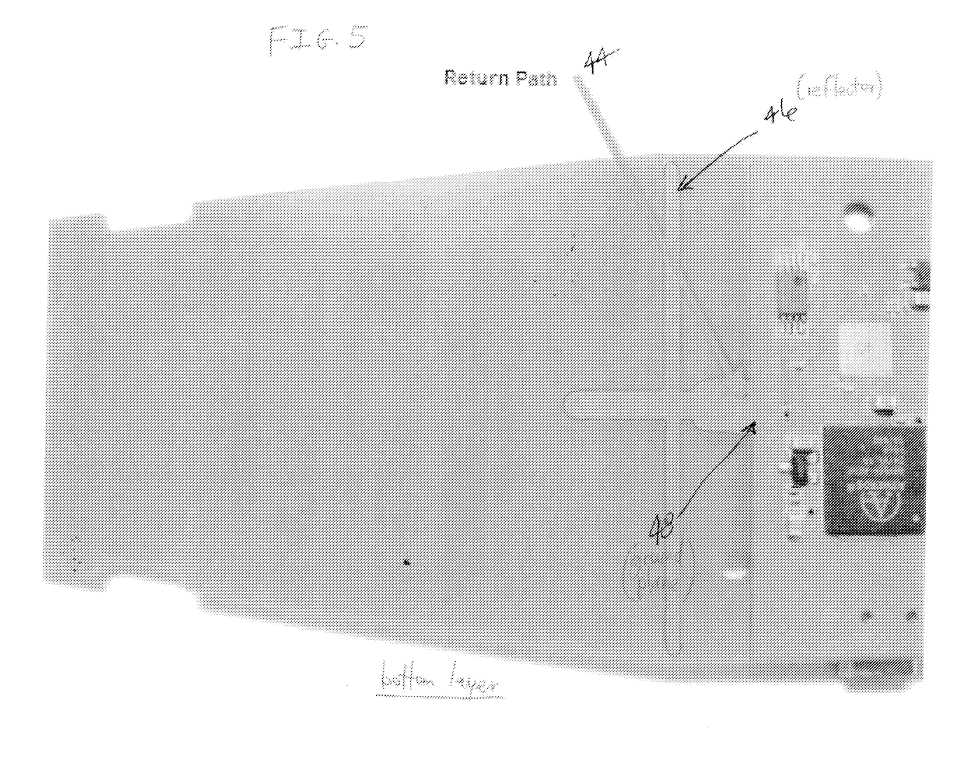

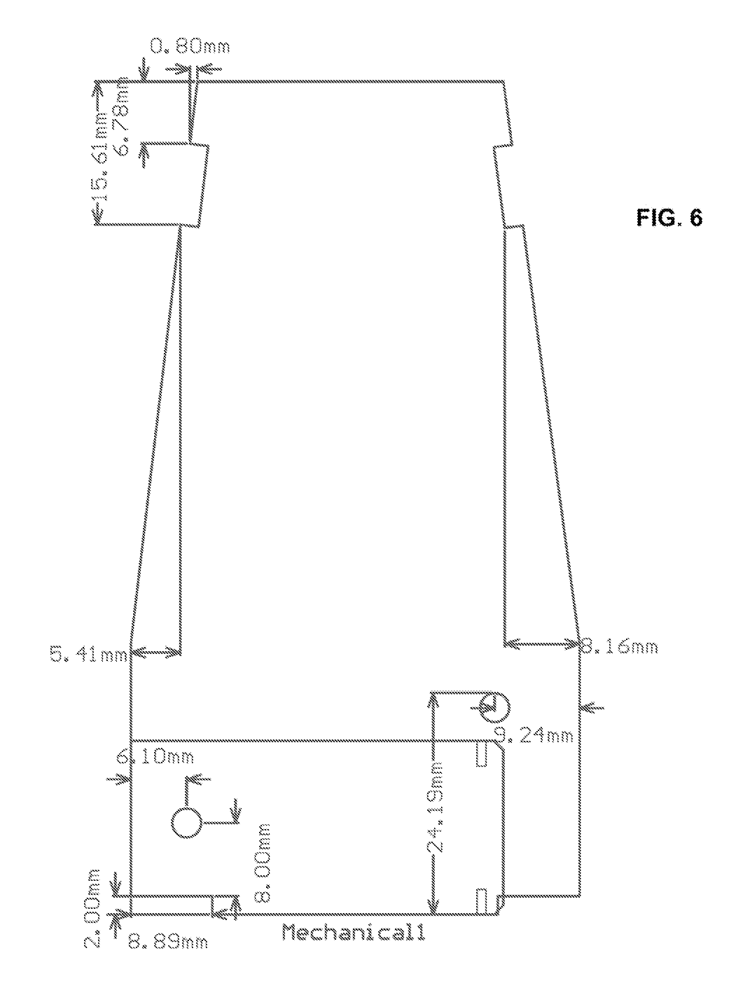

Referring now to FIG. 5, the return path 44 side of the directional antenna is shown including the reflector 46 and ground plane 48. Proper design of the return path 44 is essential to maintaining impedance control and hence maximizing signal strength and maintaining signal integrity. The addition of discrete components for impedance control of the integration of the antenna(e) to the circuitry provides additional lossiness and distortion that reduces signal strength and integrity, the latter also referred to as signal quality. Through dimensional design and control of the return path relative to the length and width of the feedline 38 and the transition from the feedline 38 to the microstrip circuit 36, the addition of discrete components for matching impedance is avoided as is the lossiness and distortion that reduces signal strength and integrity. This is counter to known design solutions, such as would be obtained using the computer model pSpice. FIG. 6 is a schematic diagram of the printed circuit board assembly 32 of FIG. 4, showing some of the interior dimensions of the board.

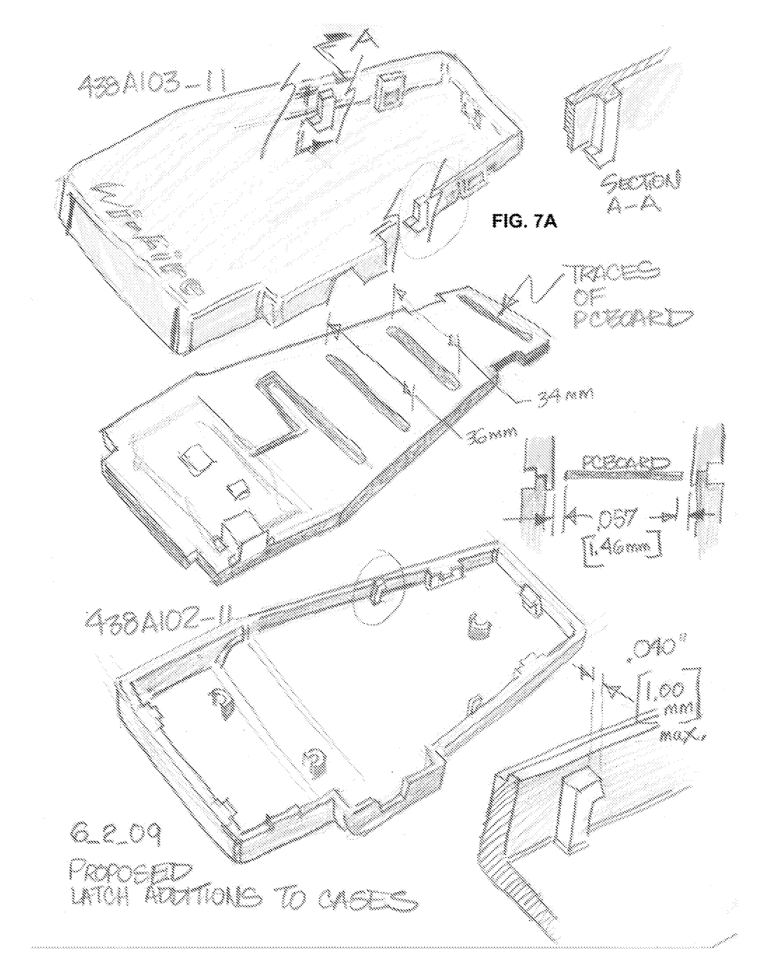

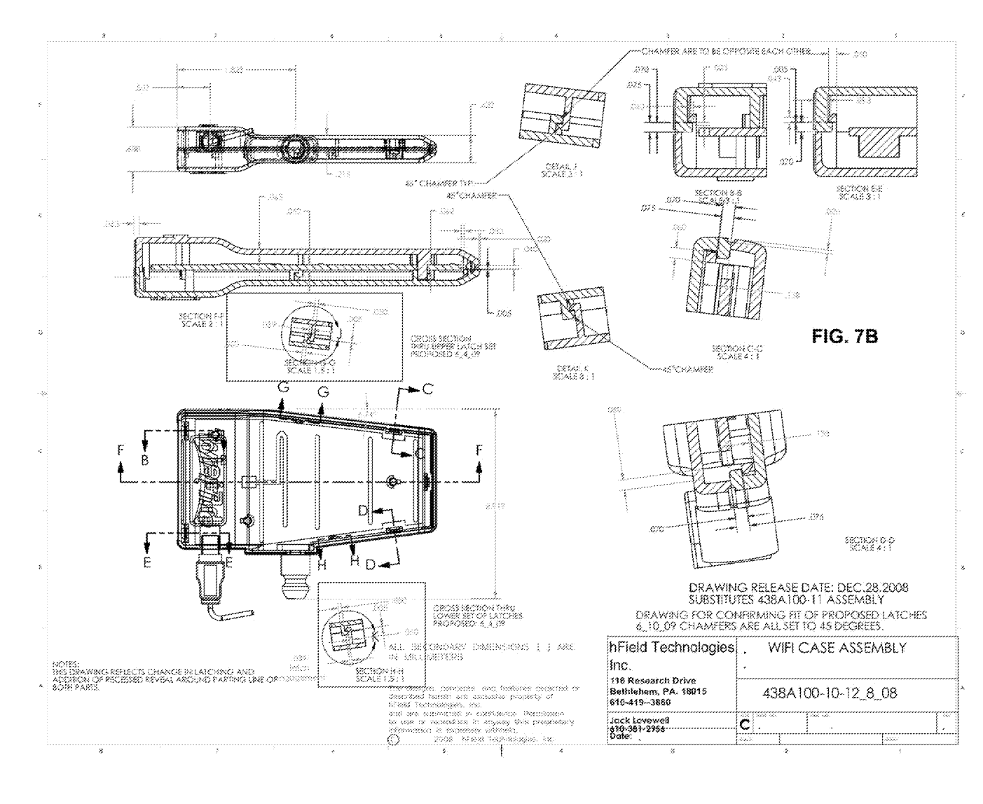

FIGS. 7A-9 refer to elements of the case 26 design which are important to maintaining impedance control. As opposed to the ease of controlling impedance in a coaxial structure, this planar structure provides special challenges due to its asymmetry. Referring to FIG. 7A, the cutouts 50 must not only accommodate the latches 52, but must provide sufficient air gap, together with the case design, in all three dimensions to prevent signal distortion at the edges of directors 53 and 54. As a general guideline, it is also important that all parts of the parallel elements of the directional antenna 12, in particular the driven element, reflector element, and the two director elements, be spaced away from any plastic parts by a minimum distance of approximately 3.0 millimeters. This is an important consideration because it is desirable to control the dielectric properties, and hence, the impedance, around these elements—particularly at the ends of each element where the signal strength is the highest. Referring to FIG. 8C, the labeled distances from the parallel antenna elements to the nearest edge of the PCB are determined such that the total distance to any case feature in any of the 3 dimensional planes, when combining the PCB and air dielectrics, is a minimum of 3.0 millimeters. These dimensions are determined to result in an electromagnetic design which is complementary to the pre-determined plastic case design and hence maximize performance results when the invention is inserted in its “complementary” case design. The 3.0 millimeter figure was selected as a general rule of thumb for spacing based on the known impedance characteristics of FR-4 (the woven glass fabric which comprises the PCB) and air. The inventors found that where spacing between the directional antenna 12 and the case 26 was at a minimum of 3.0 millimeters, then considerations of the characteristics of the ABS plastic which comprises the case 26 could effectively be ignored. As further detailed below, in areas where 3.0 millimeter spacing could not be achieved between the directional antenna 12 and the case 26, the inventors employed calculations and trial-and-error in discovering the proper design and placement for the latches 56 of the case 26.

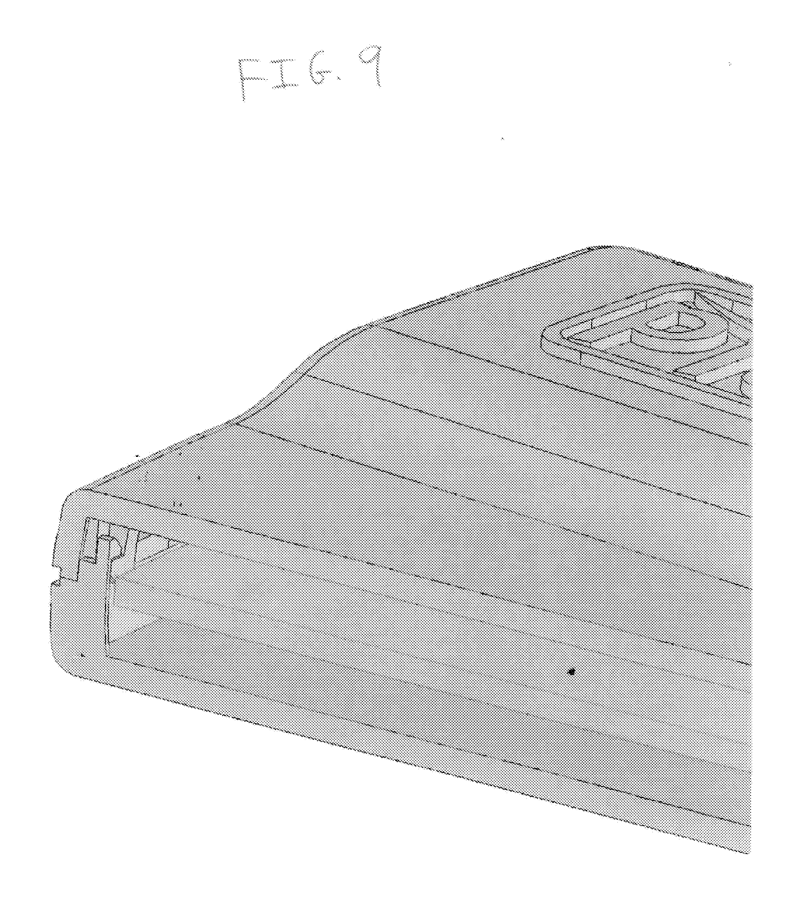

Referring now to FIG. 8A, locations for sealing the case 26 may sometimes fall in electromagnetically sensitive areas. Therefore, specially-designed, symmetrical locking latches 56 were developed which are scalable in size and mass. With this latch system, the mass of the latches 56 can be increased or decreased without changing the form factor of the latching system in order to provide impedance matching while locking the case 26 securely. Stated another way, the latches 56 were strategically sized and positioned within existing air gaps in the case 26 in order to avoid having these latches 56 impact impedance, and to some degree enhance impedance control. The combination of the PCB plus air dielectric and the elimination of any significant contribution from the case dielectric results in maximized performance. Therefore, the size of the latches 56 is adjusted and the cutouts 50 in the PCB are realized to provide the desired average dielectric constant in all 3 planes. FIG. 9 shows the latches 56 in cross section.

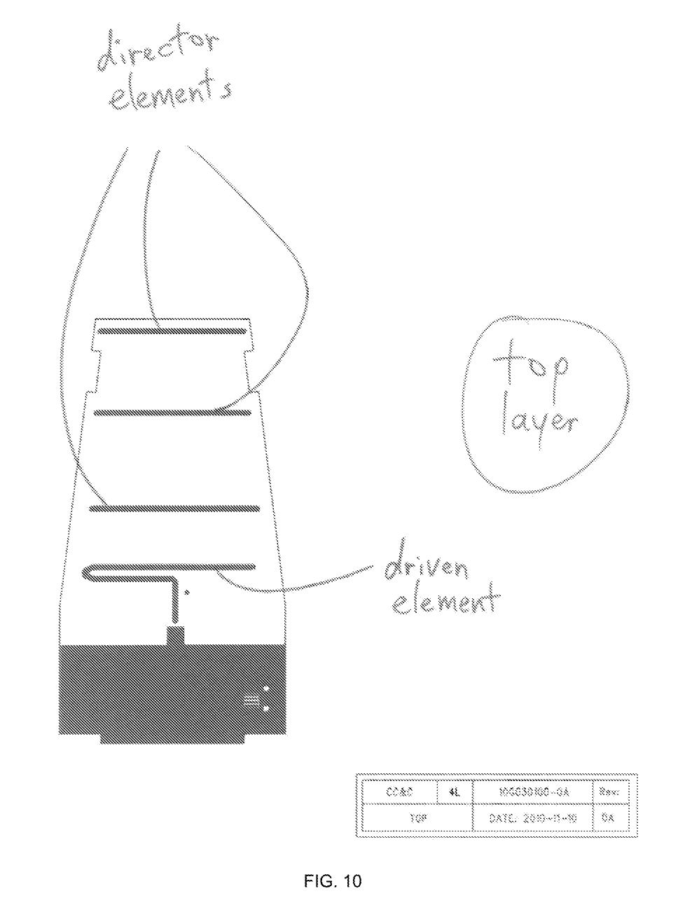

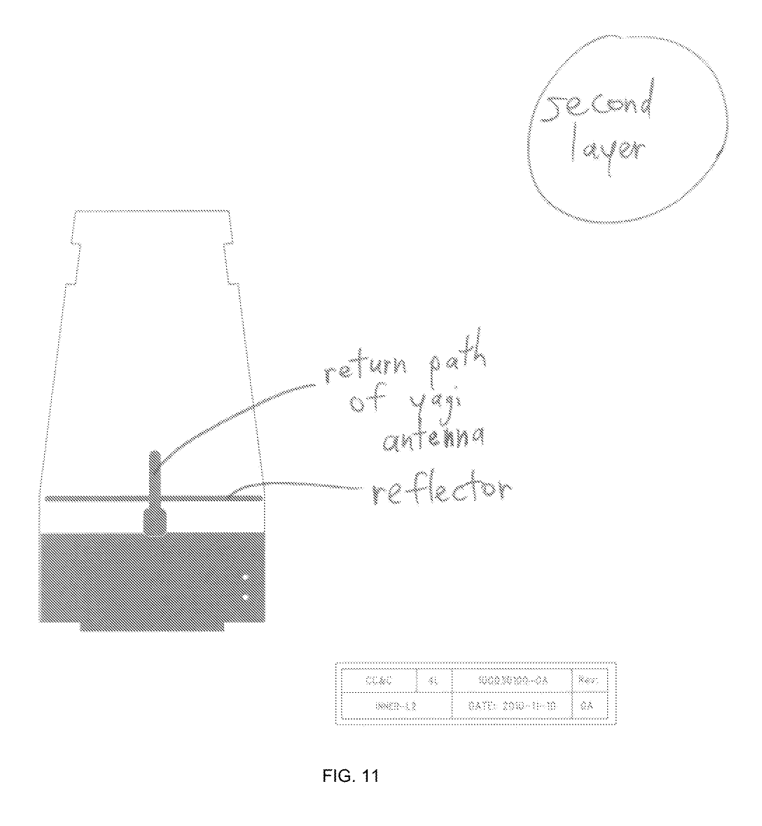

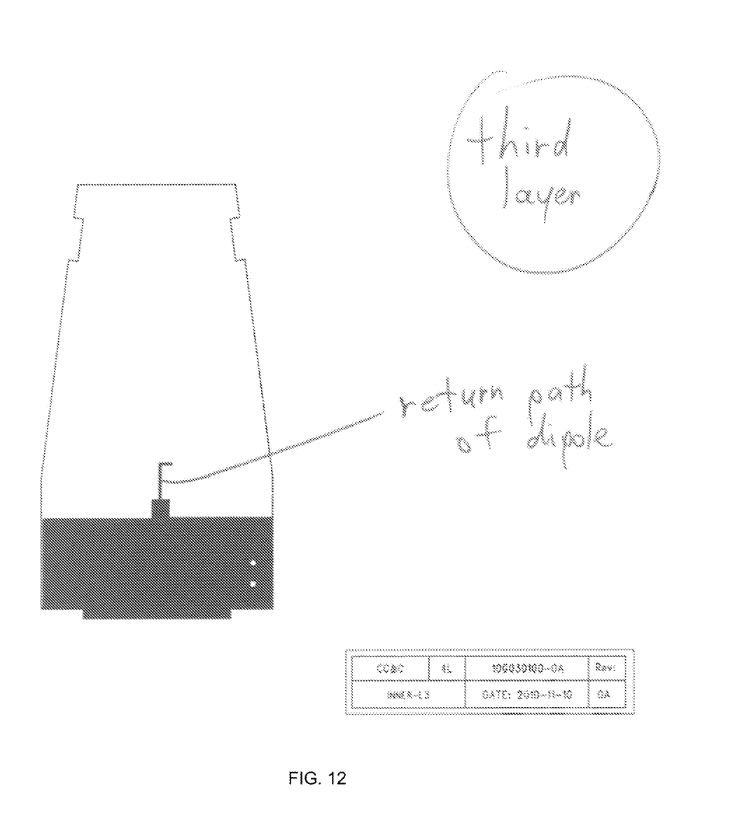

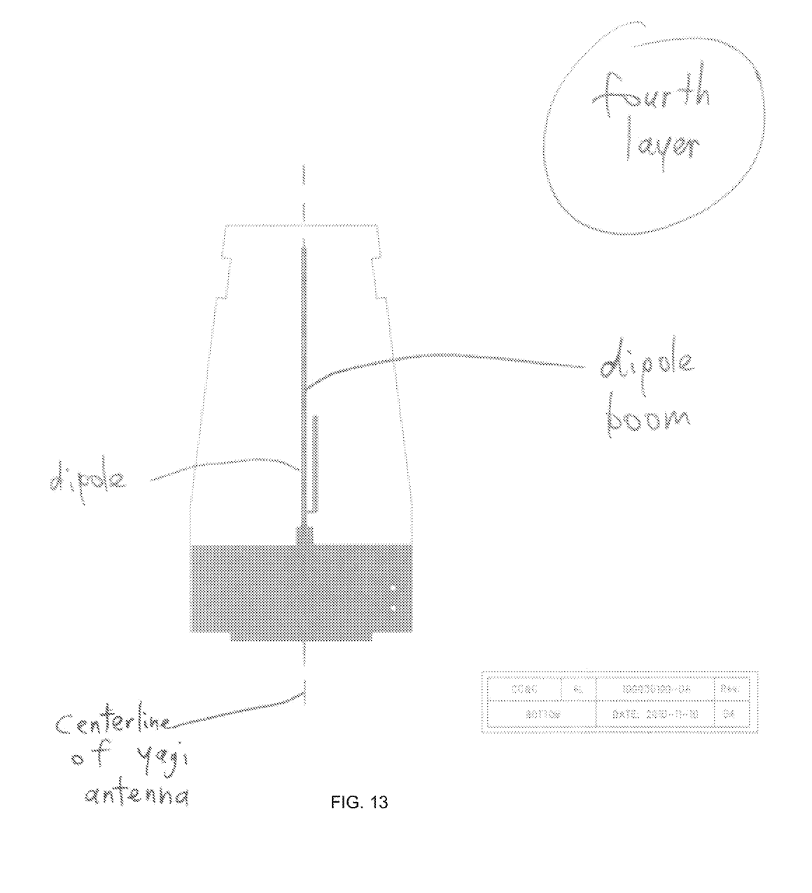

FIGS. 10-13 show schematic views of the top (first), second, third, and bottom (fourth) layers, respectively, of a second embodiment of a printed circuit board assembly in accordance with the present invention. FIG. 10 shows the top (first) layer of the printed circuit board assembly, which in this embodiment includes an active layer of a Yagi antenna, including a driven element and three director elements. FIG. 11 shows the second layer of the printed circuit board assembly, which includes a return path of the Yagi antenna and a reflector. FIG. 12 shows the third layer of the printed circuit board assembly, which includes a return path of a dipole. FIG. 13 shows the bottom (fourth) layer of the printed circuit board assembly, which includes the dipole, the dipole having a boom portion, the boom portion extending along a centerline of the Yagi antenna. In this embodiment, the dipole was placed on the bottom layer of the printed circuit board assembly in order to isolate the two antennae (Yagi and dipole) from each other. In this design, the dipole is provided for a design using two transceivers, each with their own antenna for signal diversity, as required when using MIMO. In this embodiment, the dipole is an improvement over previous versions of the invention, which provides two enhancements: (1) the Yagi has an improved operational signal distance; and (2) the power of the signal is concentrated in a narrow beam using the first, dedicated transceiver, with the dipole providing omnidirectional signal coverage over a medium distance range using the second, dedicated transceiver. This signal diversity provides high throughput even at close range, achieving similar maximum rates to the typical 802.11n devices, and also provides higher throughput than known devices under high multipath fading environments, as the Yagi will focus on only the strongest detected signals and the dipole will pick up the many reflected signals bouncing everywhere else. Field tests of devices according to the present invention show that it provides consistent signal throughput over long distances, where the signals provided by other 802.11n devices drop off quickly. Antennae according to this design may also be used for other applications, for example where the dipole is used as the input/output means for a group of computers or other devices, while the Yagi antenna can simultaneously be used to pull in weak signals (which may have traveled long distances). The Yagi can therefore be used to pull in weak signals for use by a group of devices, for example in a household having multiple computers and handheld/portable wireless devices.

In this embodiment, the Yagi antenna and dipole were integrated together in close proximity on the same substrate (i.e., the multilayered PCB assembly shown in FIGS. 10-13) in a cooperative fashion, in other words, in a way in which they do not interact or interfere with each other. In this embodiment, the Yagi antenna and dipole are located on different layers of the substrate.

In the herein disclosed embodiments, the impedance of the Yagi antenna and the impedance of the radio output were matched so as to avoid the need to employ a filter or matching circuitry, which are typically used to match impedance between the Yagi antenna and the radio transmitter(s). When a filter or matching circuit is used, the gain of the antenna is decreased because the matching circuit is draining energy from the device in order to operate. The energy used by the matching circuit is often converted into thermal energy, thereby making the system lossy. In the herein disclosed embodiments, the inventors employed calculations and trial and error to find the appropriate dimensions and placement for the feedline and the return path of the Yagi antenna in order to match the impedance of the Yagi antenna with the impedance of the ratio output, thereby rendering a filter or matching circuit unnecessary, and ensuring that the system would be capable of maximum gain.

While the principals of the invention have been described in connection with the preferred embodiments, it is to be clearly understood that this description is made only by way of example and not as a limitation of the scope of the invention.

1. A wireless networking adapter comprising:
a directional antenna; and
a decoder circuit;
wherein the directional antenna and the decoder circuit are integrally formed with a single printed circuit board.

2. The wireless networking adapter of claim 1, further comprising an omnidirectional antenna.

3. The wireless networking adapter of claim 2, wherein the omnidirectional antenna is integrally formed with the printed circuit board.

4. The wireless networking adapter of claim 3, wherein the directional antenna is a Yagi antenna.

5. A wireless networking adapter comprising a protective case, the protective case including:
a printed circuit board; and
a directional antenna,
wherein the protective case is specifically designed so that a gain measurement of the directional antenna when it is not housed in the protective case is less than a gain measurement of the directional antenna when it is housed in the protective case.

6. The wireless networking adapter of claim 5, the directional antenna further including active elements comprising a driven element, a reflector element, and at least one director element, wherein each of the active elements are spaced a minimum distance of 3.0 millimeters from any part of the protective case.

7. The wireless networking adapter of claim 5, the protective case including at least one latch, the latch being surrounded by an air gap.

8. A wireless networking adapter comprising a printed circuit board assembly substrate including a directional antenna and a dipole.

9. The wireless networking adapter of claim 8, wherein the directional antenna generates a unidirectional signal and the dipole generates an omnidirectional signal.

10. The wireless networking adapter of claim 9, wherein the directional antenna uses a first dedicated transceiver to generate the unidirectional signal and the dipole uses a second dedicated transceiver to generate the omnidirectional signal, the first and second dedicated transceivers being located on the printed circuit board assembly.

11. The wireless networking adapter of claim 8, wherein the printed circuit board assembly includes a plurality of printed layers, and the directional antenna is located on a different one of the plurality of printed layers than the dipole.

12. The wireless networking adapter of claim 11, wherein the plurality of printed layers comprises four printed layers including a top layer, a second layer, a third layer, and a bottom layer, wherein the directional antenna is located on the top layer and the dipole is located on the bottom layer.

13. The wireless networking adapter of claim 8, the dipole including a boom portion, the boom portion extending along a centerline of the directional antenna.

14. The wireless networking adapter of claim 13, wherein the directional antenna includes active elements comprising a driven element, a reflector element, and at least one director element, and the boom portion extends substantially perpendicular to each of the active elements.
